(19) United States
(12) Patent Application Publication
(10) Pub. No.: US 2009/0219748 A1
(43) Pub. Date: Sep. 3, 2009

(54) FERROELECTRIC MEMORY DEVICE

(75) Inventor: Susumu SHUTO, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/395,096

(22) Filed: Feb. 27, 2009

(30) Foreign Application Priority Data
Feb. 28, 2008 (JP) 2008-047886

(51) Int. Cl. G11C 11/22; G11C 11/24; G11C 11/416

(52) U.S. Cl. 365/145; 365/149; 365/189.011

(57) ABSTRACT

A ferroelectric memory includes ferroelectric capacitors including ferroelectric films between first electrodes and second electrodes; cell transistors; and a bit line contact connecting the cell transistors to a bit line, wherein the first electrode is connected to one of source and drain of the cell transistor at a first node, so that the ferroelectric capacitor and the cell transistor form a unit cell, the other of source and drain of the cell transistor for the unit cell is connected to the first node of other unit cell to serially connect the cell transistors for unit cells, so that the unit cells form a cell string, the word lines are connected to gates of the cell transistors or function as gates, the plate lines are connected to the second electrodes of the ferroelectric capacitors, and the bit line is connected to a cell transistor at an end of the cell string.

### CROSS-REFERENCE TO RELATED APPLICATION

This application is based upon and claims the benefit of priority from the prior Japanese Patent Applications No. 2008-47886, filed on Feb. 28, 2008, the entire contents of which are incorporated herein by reference.

### Related Art

Conventional ferroelectric memories are configured by a plurality of unit cells formed of ferroelectric capacitors and selective transistors. The ferroelectric capacitor in each unit cell is connected via the selective transistor to a bit line. That is, conventionally, bit line contacts are provided for the respective unit cells, and the bit line contact connects the bit line to the selective transistor in the memory cell.

Thus, when the bit line contact is provided for every unit cell, the size (area) of the unit cell is reduced only to 8 F² at minimum. “F” indicates a minimum feature size of photolithography in device manufacturing techniques.

### SUMMARY OF THE INVENTION

A ferroelectric memory device according to an embodiment of the present invention comprises a plurality of word lines; a plurality of bit lines; a plurality of plate lines; a plurality of ferroelectric capacitors each of which includes a ferroelectric film between a first electrode and a second electrode; a plurality of cell transistors corresponding to the ferroelectric capacitors; and a bit line contact connecting the cell transistors to the bit line, wherein

the first electrode is connected to one of source and drain of the cell transistor at a first node, so that the ferroelectric capacitor and the cell transistor form a unit cell,

the other of source and drain of the cell transistor for the unit cell is connected to the first node of other unit cell to serially connect the cell transistors for a plurality of unit cells, so that the unit cells form a cell string,

the word lines are connected to gates of the cell transistors or function as gates,

the plate lines are connected to the second electrodes of the ferroelectric capacitors, and

the bit line is connected only to a cell transistor at an end of the cell string via the bit line contact.

A ferroelectric memory device according to an embodiment of the present invention comprises a plurality of word lines; a plurality of bit lines; a plurality of plate lines connected to each other as a common plate; a plurality of ferroelectric capacitors each of which includes a ferroelectric film between a first electrode and a second electrode; a plurality of cell transistors corresponding to the ferroelectric capacitors; and a bit line contact connecting the cell transistors to the bit line, wherein

the first electrode is connected to one of source and drain of the cell transistor at a first node, so that the ferroelectric capacitor and the cell transistor form a unit cell,

the other of source and drain of the cell transistor for the unit cell is connected to the first node of other unit cell to serially connect the cell transistors for a plurality of unit cells, so that the unit cells form a cell string,

the word lines are connected to gates of the cell transistors or function as gates,

the common plate is connected to the second electrodes of the ferroelectric capacitors, and

the bit line is connected only to a cell transistor at an end of the cell string via the bit line contact.

### BRIEF DESCRIPTION OF THE DRAWINGS

FIG. 1 shows a configuration of a ferroelectric memory according to a first embodiment of the present invention;

FIG. 2 is a cross-sectional view showing a configuration of the cell string CS according to the first embodiment;

FIG. 3 is an equivalent circuit diagram of the cell string CS shown in FIG. 2;

FIGS. 4 and 5 are conceptual diagrams showing an operation for writing data in the ferroelectric memory according to the first embodiment;

FIG. 6 is a timing chart showing the potentials of the word line WL, the bit line BL, and the plate line PL when the data is written in the unit cell UC4;

FIGS. 7 to 9 are conceptual diagrams showing an operation for reading data from the ferroelectric memory according to the first embodiment;

FIG. 10 is a timing chart showing the potentials of the word line WL, the bit line BL, and the plate line PL when the data is written in the unit cell UC1;

FIG. 11 shows a configuration of a ferroelectric memory according to a second embodiment of the present invention;

FIG. 12 is a cross-sectional view showing a configuration of the cell string CS according to the second embodiment; and

FIG. 13 is an equivalent circuit diagram of the cell string CS shown in FIG. 12.

### DETAILED DESCRIPTION OF THE INVENTION

Embodiments of the present invention will be explained below in detail with reference to the accompanying drawings. Note that the invention is not limited thereto.

### First Embodiment

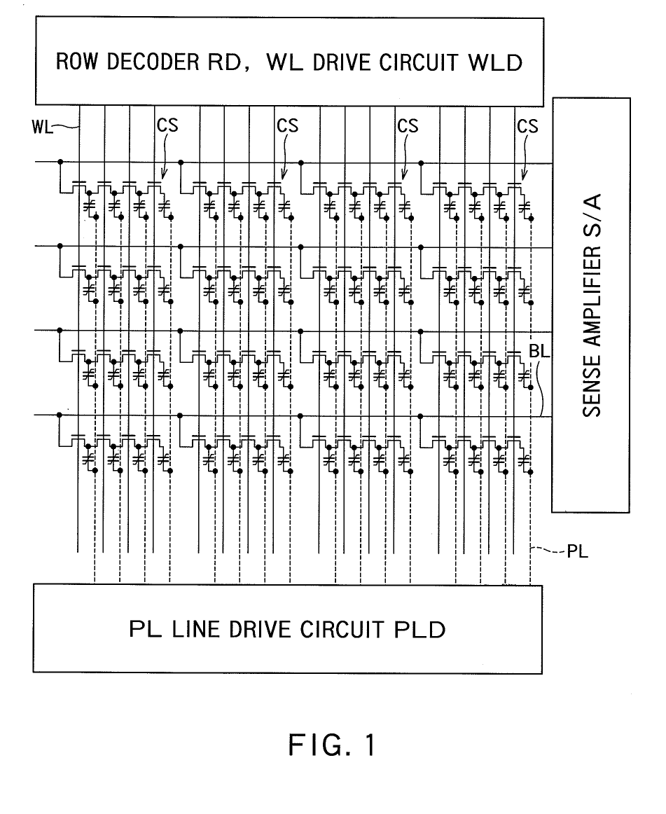

FIG. 1 shows a configuration of a ferroelectric memory according to a first embodiment of the present invention. The ferroelectric memory according to the first embodiment includes a plurality of word lines WL extending in a row direction, a plurality of bit lines BL extending in a column direction perpendicular to the row direction, and a plurality of plate lines PL extending in the row direction. The plate line PL is indicated by a broken line so as to be distinguished from the word line in FIG. 1.

A ferroelectric capacitor and a cell transistor (selective transistor) constitute a unit cell. Four serially connected unit cells constitute a cell string CS. The unit cell is a memory cell that stores binary data or multi-bit data in the ferroelectric capacitor. The unit cell is two-dimensionally arranged in a matrix on a semiconductor substrate. The unit cell is provided at the intersection of the word line and the bit line. Every word line WL is for the unit cells arranged in the row direction. Every bit line BL is for the unit cells arranged in the column direction. Every plate line PL is for the unit cells arranged in the row direction.

The word lines WL are connected to a word line drive circuit WLD. The word line drive circuit WLD selects a part of the word line (or word lines) WL based on addresses received from a row decoder RD and applies a voltage to the selected word lines WL. The bit lines BL are connected to a sense amplifier S/A. The sense amplifier S/A detects data from the unit cells transmitted through the bit lines during data reading. At the time of data writing, the sense amplifier S/A selects a part of the bit line (or bit lines) BL and applies a voltage to the selected bit lines BL. Accordingly, the sense amplifier S/A can write data through the bit line BL in the unit cells connected to the selected word line. Thus, the application of voltage to the word line WL and the bit line BL enables the data to be written in or read from the unit cell at their intersection. Because the bit line BL is connected only to a unit cell at an end of the cell string CS in the first embodiment, reading and writing operations are different from conventional ones as described later. The reading and writing operations of the first embodiment will be described later.

FIG. 1 shows the unit cells arranged in a 16×4 matrix (cell strings arranged in a 4×4 matrix). However, the number of the unit cells (cell strings) is not limited thereto.

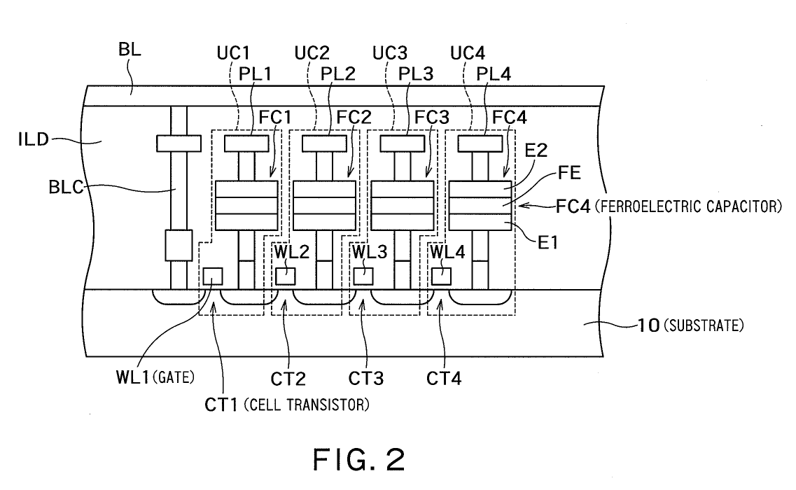

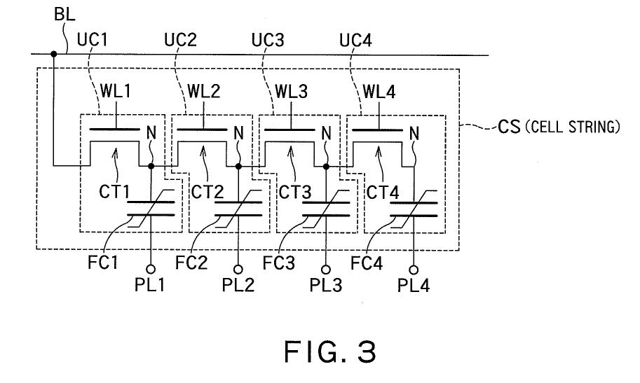

FIG. 2 is a cross-sectional view showing a configuration of the cell string CS according to the first embodiment. FIG. 3 is an equivalent circuit diagram of the cell string CS shown in FIG. 2. Because FIG. 2 shows a cross-section along the bit line BL, only one bit line BL is shown in FIG. 2.

A ferroelectric memory includes a plurality of ferroelectric capacitors FC1 to FC4 and a plurality of cell transistors CT1 to CT4. The ferroelectric capacitor FC has a first electrode E1, a second electrode E2, and a ferroelectric film FE between the first electrode E1 and the second electrode E2. The cell transistors CT1 to CT4 correspond to the ferroelectric capacitors FC1 to FC4, respectively.

For each of the ferroelectric capacitors FC1 to FC4, the first electrode E1 is connected to one of the source and drain (for example, source) of each of the cell transistors CT1 to CT4 at a first node N. The first nodes N are connection nodes between the first electrodes E1 of the ferroelectric capacitors FC1 to FC4 and the cell transistors CT1 to CT4, respectively. Thus, the ferroelectric capacitors FC1 to FC4 are serially connected to the respective cell transistors CT1 to CT4 to constitute the unit cells UC1 to UC4. That is, the ferroelectric capacitor FC1 and cell transistor CT1 constitute the unit cell UC1, the ferroelectric capacitor FC2 and cell transistor CT2 constitute the unit cell UC2, the ferroelectric capacitor FC3 and cell transistor CT3 constitute the unit cell UC3, and the ferroelectric capacitor FC4 and cell transistor CT4 constitute the unit cell UC4.

Further, for each of the cell transistors CT1 to CT4, the other of the source and drain (for example, drain) is connected to the first node N of an adjacent unit cell. Thus, the cell transistors CT1 to CT4 are thus serially connected and the unit cells UC1 to UC4 constitute one cell string CS. While the cell string CS includes four unit cells UC1 to UC4 according to the first embodiment, the cell string CS can include three or less, or five or more unit cells.

The word lines WL1 to WL4 also function as the gates of the cell transistors CT1 to CT4. Alternatively, word lines are formed independently from the gates of the cell transistors CT1 to CT4 and the word lines are connected to the gates of the cell transistors CT1 to CT4 using contacts.

The plate lines PL1 to PL4 are connected to the respective second electrodes E2 of the ferroelectric capacitors FC1 to FC4. Further, the bit line BL is connected via a bit line contact BLC to the other of source and drain (for example, drain) of the cell transistor CT1 at an end of the cell string CS. Therefore, the bit line contact BLC that passes through an interlayer dielectric layer ILD to connect the cell transistor CT1 to the bit line BL is provided only at an end of the cell string CS (unit cell UC1 side) and does not correspond to the respective unit cells. As clearly shown in FIG. 1, the bit line contact BLC is provided only at an end of the cell string CS.

Thus, only one bit line contact BLC is provided for a plurality of unit cells (for a cell string) according to the first embodiment. Accordingly, an occupied area per unit cell is smaller than the one for conventional ferroelectric memories. The ferroelectric memory according to the first embodiment is thus suitable for high integration.

### (Writing Operation)

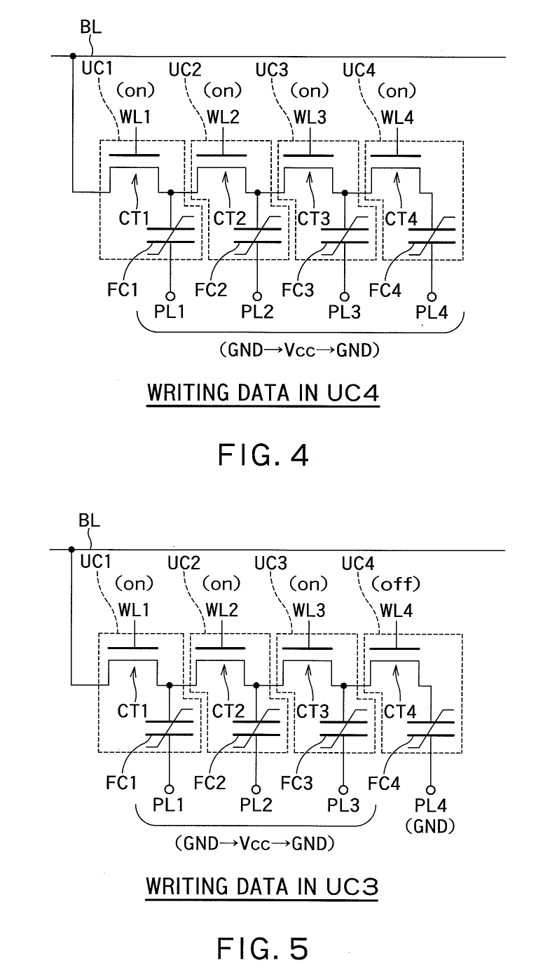

FIGS. 4 and 5 are conceptual diagrams showing an operation for writing data in the ferroelectric memory according to the first embodiment. FIGS. 4 and 5 show only one cell string CS. FIG. 4 shows the cell string CS when the data is written in the unit cell UC4. FIG. 5 shows the cell string CS when the data is written in the unit cell UC3.

Data writing begins at the unit cell UC4 which is farthest from the bit line BL among the unit cells UC1 to UC4 included in the cell string CS.

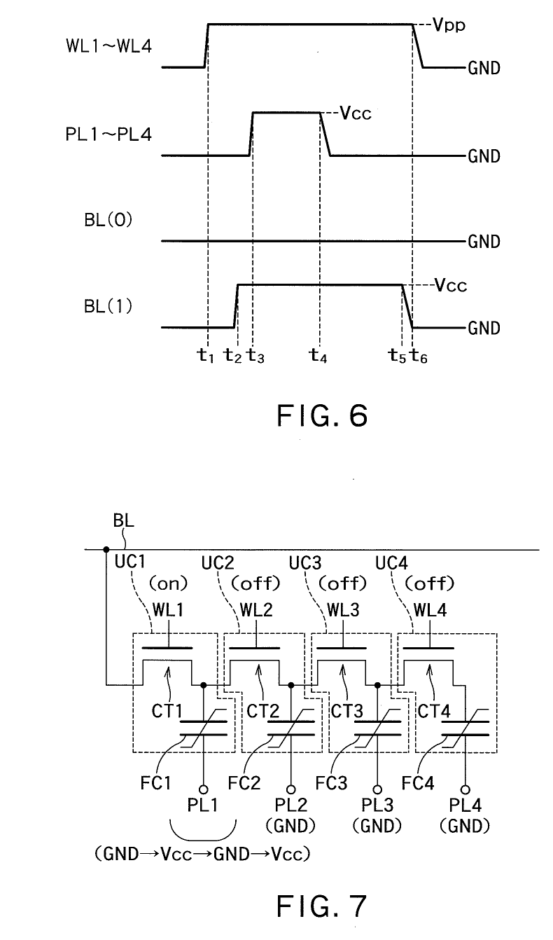

When the data is written in the unit cell UC4, the word lines WL1 to WL4 are all turned on as shown in FIG. 4. For example, if the cell transistor is an N-type FET, the word lines WL1 to WL4 have a high level potential (Vpp). Accordingly, the word line drive circuit WLD turns on the cell transistor CT4 of the unit cell UC4 to be written and the cell transistors CT1 to CT3 between the unit cell UC4 and the bit line BL. Because the cell transistors CT1 to CT4 are all on, the bit line BL is electrically connected to the unit cell UC4. A low level potential (ground potential GND) or a high level potential (Vcc) is applied to the bit line BL depending on the data to be written as shown in FIG. 6. For example, if data “1” is to be written, the high level potential Vcc is applied to the bit line BL. If data “0” is to be written, the low level potential is applied to the bit line BL. BL(0) in FIG. 6 indicates a bit line potential when the data “0” is written, while BL(1) indicates a bit line potential when the data “1” is written. On this condition, all plate lines PL1 to PL4 are changed like GND→Vcc→GND as shown in FIG. 6. The data is thus written in the unit cell UC4.

FIG. 6 is a timing chart showing the potentials of the word line WL, the bit line BL, and the plate line PL when the data is written in the unit cell UC4. The word line drive circuit WLD raises the potentials of the word lines WL1 to WL4 to the high level potential Vpp at t1. The cell transistors CT1 to CT4 shown in FIG. 4 are thus turned on. The sense amplifier S/A applies a potential (Vcc or GND) depending on the data to be written to the bit line at t2.

A plate line drive circuit PLD raises the plate lines PL1 to PL4 to the high level potential Vcc at t3 and reduces them to the ground potential at t4. The data is written in the ferroelectric capacitors FC1 to FC4 because of the potential difference between the bit line and the plate line.

More specifically, if the data “0” is written, a potential difference (−Vcc) is applied between the first electrodes E1 and the second electrodes E2 of the ferroelectric capacitors FC1 to FC4 at t3 to t4. Polarization states of the ferroelectric capacitors FC1 to FC4 are determined and the data “0” is written. The potential difference applied to the ferroelectric capacitor is the potential of the first electrode E1 on the bit line side with respect to the second electrode E2 on the plate line side. Negative potential difference means that the bit line potential is lower than the plate line potential. The potential difference applied between the first electrodes E1 and the second electrodes E2 of the ferroelectric capacitors FC1 to FC4 at t4 to t5 is substantially zero. The polarization states of the ferroelectric capacitors FC1 to FC4 do not change and the ferroelectric capacitors FC1 to FC4 hold the data “0”.

When the data “1” is written, the potential difference applied between the first electrodes E1 and the second electrodes E2 of the ferroelectric capacitors FC1 to FC4 at t3 to t4 is substantially zero. Therefore, the polarization states of the ferroelectric capacitors FC1 to FC4 do not change. The potential difference (+Vcc) is applied between the first electrodes E1 and the second electrodes E2 of the ferroelectric capacitors FC1 to FC4 at t4 to t5. Accordingly, the polarization states of the ferroelectric capacitors FC1 to FC4 are determined and the data “1” is written.

The sense amplifier S/A then reduces the bit line BL(1) at t5. The word line drive circuit WLD reduces the word lines WL1 to WL4 at t6.

An operation when the data is written in the unit cell UC3 is explained next with reference to FIG. 5. At the time of writing the data in the unit cell UC3, the unit cell UC4 has already stored the data. Thus, the word line WL4 is set to a low level potential and the cell transistor CT4 is turned off. Meanwhile, to connect the unit cell UC3 to the bit line BL, the word line drive circuit WLD applies the high level potential (Vpp) to the word lines WL1 to WL3. Therefore, the cell transistor CT3 of the unit cell UC3 to be written and the cell transistors CT1 and CT2 between the unit cell UC3 and the bit line BL are all turned on. As a result, the ferroelectric capacitors FC1 to FC3 are connected to the bit line BL while the ferroelectric capacitor FC4 is isolated from the bit line BL.

As described with reference to FIG. 6, the low level potential (ground potential) or the high level potential (Vcc) is applied to the bit line BL depending on the data to be written. On this condition, the plate lines PL1 to PL3 are then changed like GND→Vcc→GND as shown in FIG. 6. Thus, the data is written in the unit cell UC3. Meanwhile, because the plate line PL4 is kept at the ground potential, the data which has already been stored in the unit cell UC4 is held.

At the time of writing the data in the unit cell UC2, the unit cells UC3 and UC4 have already stored the data. Thus, the word lines WL3 and WL4 are set to the low level potential and the cell transistors CT3 and CT4 are turned off. Meanwhile, to connect the unit cell UC2 to the bit line BL, the word line drive circuit WLD applies the high level potential (Vpp) to the word lines WL1 and WL2. Accordingly, the cell transistor CT2 of the unit cell UC2 to be written and the cell transistor CT1 between the unit cell UC2 and the bit line BL are turned on. As a result, the ferroelectric capacitors FC1 and FC2 are connected to the bit line BL while the ferroelectric capacitors FC3 and FC4 are isolated from the bit line BL.

As described with reference to FIG. 6, the low level potential (ground potential) or the high level potential (Vcc) is applied to the bit line BL depending on the data to be written. On this condition, the plate lines PL1 and PL2 are then changed like GND→Vcc→GND as shown in FIG. 6. Thus, the data is written in the unit cell UC2. Because the plate lines PL3 and PL4 are kept at the ground potential, the data already written in the unit cells UC3 and UC4 are held. Because the data writing operation for the unit cell UC2 is easily assumed from FIGS. 4 to 6, illustrations of the operation will be omitted.

Further, at the time of writing the data in the unit cell UC1, the unit cells UC2 to UC4 have already stored the data. Thus, the word lines WL2 to WL4 are set to the low level potential and the cell transistors CT2 to CT4 are turned off. Meanwhile, to connect the unit cell UC1 to the bit line BL, the word line drive circuit WLD applies the high level potential (Vpp) to the word line WL1. Only the cell transistor CT1 of the unit cell UC1 to be written is turned on. As a result, the ferroelectric capacitor FC1 is connected to the bit line BL while the ferroelectric capacitors FC2 to FC4 are isolated from the bit line BL.

As described with reference to FIG. 6, the low level potential (ground potential) or the high level potential (Vcc) is applied to the bit line BL depending on the data to be written. On this condition, only the plate line PL1 is then changed like GND→Vcc→GND as shown in FIG. 6. Thus, the data is written in the unit cell UC1. Meanwhile, because the plate lines PL2 to PL4 are kept at the ground potential, the data already written in the unit cells UC2 to UC4 are held. Because the data writing operation for the unit cell UC1 is easily assumed from FIGS. 4 to 6, illustrations of the operation will be omitted.

The writing operation is performed, among unit cells included in the cell string CS, in the order from a unit cell farthest from the bit line BL to a unit cell closer to the bit line BL. When the data is written in the unit cell UC4 farthest from the bit line BL, the same data is also written in the unit cells UC1 to UC3 between the bit line BL and the unit cell UC4. However, the data is then written (updated) in the unit cells UC3, UC2, and UC1 in this order. Therefore, problems do not occur if the same data is written in the unit cells UC1 to UC3 at the time of writing the data in the unit cell UC4. When the data is written in the unit cell UC3, the same data is also written in the unit cells UC1 and UC2. However, because the data is then updated in the order of the unit cell UC2 and unit cell UC1, problems do not occur. Further, when the data is written in the unit cell UC2, the same data is also written in the unit cell UC1. However, because the data is then updated in the unit cell UC1, problems do not occur.

### (Reading Operation)

A reading operation is performed in the order from the unit cell UC1 close to the bit line BL to the unit cell UC4 farthest from the bit line BL, which is opposite to the writing operation.

FIGS. 7 to 9 are conceptual diagrams showing an operation for reading data from the ferroelectric memory according to the first embodiment. The bit line BL is first precharged to a ground potential GND. The bit line BL is then disconnected from the sense amplifier S/A to be in a high impedance state.

The word line drive circuit WLD raises the potential of the word line WL1 to a high level potential (Vpp), so that the cell transistor CT1 is turned on as shown in FIG. 7. Meanwhile, the word line drive circuit WLD keeps the word lines WL2 to WL4 at a low level potential (GND), so that the cell transistors CT2 to CT4 are turned off. Accordingly, only the ferroelectric capacitor FC1 is connected to the bit line BL.

On this condition, the plate line drive circuit PLD changes only the plate line PL1 from the low level potential (GND) to the high level potential (Vcc). Thus, electric charges accumulated depending on the polarization state of the ferroelectric capacitor FC1 are flown in the bit line BL, causing the potential of the bit line BL to be changed. The sense amplifier S/A detects such change in the potential of the bit line BL. The data stored in the unit cell UC1 is thus read.

The potential of the plate line PL1 is then returned to the low potential level and the data “0” is then written in the unit cell UC1 as dummy data. To write the data “0”, after the reading operation, the potential of the bit line BL is set to the low level potential (GND) and the potential of the plate line PL is raised to Vcc while the potential of the word line WL is kept at the high level potential (Vpp). Thus, the data “0” is written in the ferroelectric capacitor FC1.

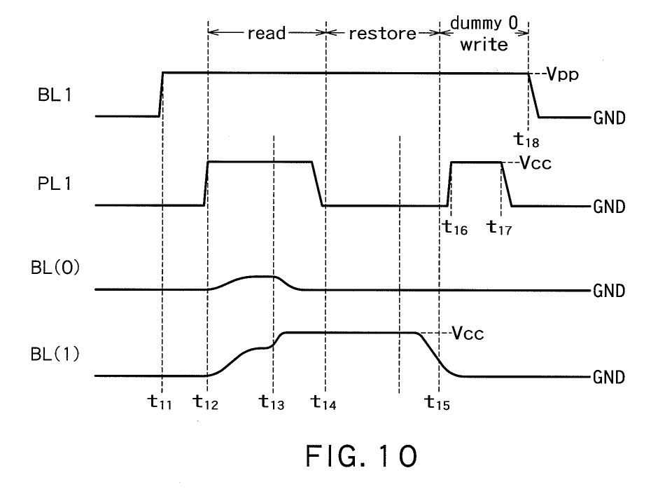

FIG. 10 is a timing chart showing the potentials of the word line WL, the bit line BL, and the plate line PL when the data is written in the unit cell UC1. The operation for reading the data from the unit cell UC1 is explained below in detail with reference to FIG. 10.

The word line drive circuit WLD raises the potential of the word line WL1 to the high level potential Vpp at t11. The cell transistor CT1 shown in FIG. 7 is turned on. The word lines WL2 to WL4 are kept at the low level potential GND and the cell transistors CT2 to CT4 are thus turned off. Thus, only the ferroelectric capacitor CF1 is connected to the bit line BL.

The plate line drive circuit PLD raises the potential of the plate line PL1 to the high level potential Vcc at t12. Accordingly, electric charges corresponding to the polarization state of the ferroelectric capacitor FC1 are flown in the bit line BL. For example, when the ferroelectric capacitor FC1 stores the data “0”, a current flowing from the ferroelectric capacitor FC1 to the bit line BL is relatively small. Meanwhile, when the ferroelectric capacitor FC1 stores the data “1”, the current flowing from the ferroelectric capacitor FC1 to the bit line BL is relatively large.

The sense amplifier S/A compares reference data to the read data and amplifies the read data at t13. The reference data is a potential or a current between the data “0” and the data “1”. If the data “0” is read, the potential or the current of the bit line BL is smaller than the reference data. The potential of the bit line BL is thus the low level potential GND as indicated by BL(0) in FIG. 10. If the data “1” is read, the potential or the current of the bit line BL is larger than the reference data. Therefore, the potential of the bit line BL is amplified to the high level potential Vcc as indicated by BL(1) in FIG. 10.

The plate line PL1 is returned to the low level potential GND at t14. Thus, data with the same logic as the read data is written in the ferroelectric capacitor FC1.

The sense amplifier S/A reduces the potential of the bit line BL to the low level potential GND at t15. The plate line drive circuit PLD raises the plate line PL1 to the high level potential Vcc at t16. The data “0” is then written in the ferroelectric capacitor FC1. The potential of the plate line PL1 is returned to the low level potential GND at t17 and the potential of the word line WL1 is reduced to the low level potential GND at t18. The data reading operation for the unit cell UC1 is thus completed. The data “0” writing operation at t15 to t17 is called dummy “0” writing. Reasons for performing the dummy “0” writing are as follows.

In the first embodiment, an output signal amount of the bit line BL is determined by its capacitance and capacitive coupling to the ferroelectric capacitor. Cell transistors between the unit cell to be read and the bit line are all turned on in the first embodiment. For example, if the data of the unit cell UC2 is read, an apparent capacitance of the bit line BL is, when seen from the ferroelectric capacitor FC2, a capacitance obtained by adding the capacitance of the ferroelectric capacitor FC1 to the capacitance of the bit line BL as a parasitic capacitance. Therefore, if the data stored in the ferroelectric capacitor FC1 is not determined, the apparent capacitance of the bit line BL (“capacitance of the bit line BL”+“capacitance of the ferroelectric capacitor FC1”) cannot be uniquely determined at the time of reading the data from the unit cell UC2. This means that the data in the unit cell UC2 varies depending on the data in the unit cell UC1. Because the reference data is fixed, the sense amplifier S/A may detect wrong data in such a case. To solve this problem, the dummy “0” writing is performed in the unit cell UC1. The apparent capacitance of the bit line BL is thus fixed when the data is read from the unit cell UC2, so that wrong data detection is prevented. In the present embodiment, the dummy data is “0”. However, “1” may be used as the dummy data. In this case, instead of changing the voltage of the plate line PL1 to the high level potential Vcc after t15 shown in FIG. 10, the voltages of the BL(0) and BL(1) should be changed to the high level potential Vcc.

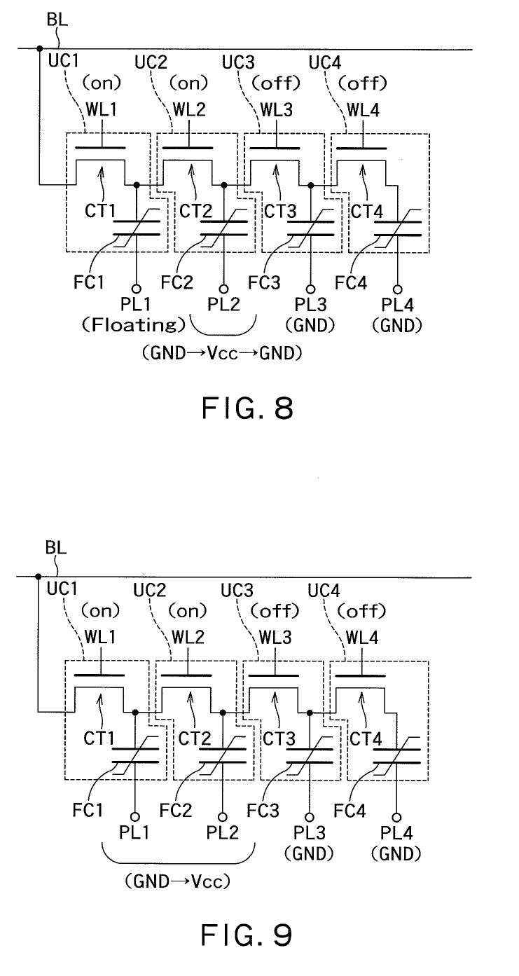

An operation for reading the data in the unit cell UC2 is explained next with reference to FIG. 8. The bit line BL is precharged to the ground potential GND. The bit line BL is then disconnected from the sense amplifier S/A so as to be in the high impedance state.

The word line drive circuit WLD raises the potentials of the word lines WL1 and WL2 to the high level potential (Vpp), causing the cell transistors CT1 and CT2 to be turned on as shown in FIG. 8. Meanwhile, the word line drive circuit WLD keeps the word lines WL3 and WL4 at the low level potential (GND), so that the cell transistors CT3 and CT4 are turned off. Only the ferroelectric capacitors FC1 and FC2 are thus connected to the bit line BL.

On this condition, the plate line drive circuit PLD changes only the plate line PL2 from the low level potential (GND) to the high level potential (Vcc). Accordingly, electric charges accumulated depending on the polarization state of the ferroelectric capacitor FC2 are flown in the bit line BL, causing the potential of the bit line BL to be changed. The plate line PL1 is in a floating state. The sense amplifier S/A detects such change in the potential of the bit line BL. The data stored in the unit cell UC2 is thus read.

The apparent capacitance of the bit line BL is larger than the capacitance when the data is read from the unit cell UC1 by the capacitance of the ferroelectric capacitor FC1 as described above. Therefore, the reference data used for reading the data in the unit cell UC2 must have lower potential or lower current than that of the reference data used for reading the data in the unit cell UC1.

Thereafter, the potential of the plate line PL2 is returned temporarily to the low level potential GND. The dummy “0” writing is then performed. As shown in FIG. 10, the sense amplifier S/A reduces the potential of the bit line BL to the low level potential GND. The plate line drive circuit PLD raises the plate lines PL1 and PL2 to the high level potential Vcc as shown in FIG. 9. The data “0” is thus written in the ferroelectric capacitors FC1 and FC2.

An operation for reading the data in the unit cell UC3 is explained below. The bit line BL is precharged to the ground potential GND. The bit line BL is then disconnected from the sense amplifier S/A so as to be in the high impedance state.

The word line drive circuit WLD raises the potentials of the word lines WL1 to WL3 to the high level potential (Vpp), causing the cell transistors CT1 to CT3 to be turned on. Meanwhile, the word line drive circuit WLD keeps the word line WL4 at the low level potential (GND), so that only the cell transistor CT4 is turned off. The ferroelectric capacitors FC1 to FC3 are connected to the bit line BL.

On this condition, the plate line drive circuit PLD changes only the plate line PL3 from the low level potential (GND) to the high level potential (Vcc). Accordingly, electric charges accumulated depending on the polarization state of the ferroelectric capacitor FC3 are flown in the bit line BL, causing the potential of the bit line BL to be changed. At this time, the plate lines PL1 and PL2 are in the floating state. The sense amplifier S/A detects such change in the potential of the bit line BL. Thus, the data stored in the unit cell UC3 is read.

The apparent capacitance of the bit line BL (“capacitance of the bit line BL”+“capacitance of FC1”+“capacitance of FC2”) is larger than the capacitance when the data is read from the unit cell UC2 by the capacitance of the ferroelectric capacitor FC2. Therefore, the reference data used for reading the data in the unit cell UC3 must have lower potential or lower current than that of the reference data used for reading the data in the unit cell UC2.

Thereafter, the potential of the plate line PL3 is returned temporarily to the low level potential GND. The dummy “0” writing is then performed. At this time, as shown in FIG. 10, the sense amplifier S/A reduces the potential of the bit line BL to the low level potential GND. The plate line drive circuit PLD raises the plate lines PL1 to PL3 to the high level potential Vcc. The data “0” is thus written in the ferroelectric capacitors FC1 to FC3.

An operation for reading the data in the unit cell UC4 is explained next. The bit line BL is precharged to the ground potential GND. The bit line BL is then disconnected from the sense amplifier S/A so as to be in the high impedance state.

The word line drive circuit WLD raises the potentials of the word lines WL1 to WL4 to the high level potential (Vpp), causing the cell transistors CT1 to CT4 to be turned on. The ferroelectric capacitors FC1 to FC4 are thus connected to the bit line BL.

On this condition, the plate line drive circuit PLD changes only the plate line PL4 from the low level potential (GND) to the high level potential (Vcc). Accordingly, electric charges accumulated depending on the polarization state of the ferroelectric capacitor FC4 are flown in the bit line BL, causing the potential of the bit line BL to be changed. At this time, the plate lines PL1 to PL4 are in the floating state. The sense amplifier S/A detects such change in the potential of the bit line BL. Thus, the data stored in the unit cell UC4 is read.

The apparent capacitance of the bit line BL (“capacitance of the bit line BL”+“capacitance of FC1”+“capacitance of FC2”+“capacitance of FC3”) is larger than the capacitance when the data is read from the unit cell UC3 by the capacitance of the ferroelectric capacitor FC3. Therefore, the reference data used for reading the data in the unit cell UC4 must have lower potential or lower current than that of the reference data used for reading the data in the unit cell UC3.

Thereafter, the potential of the plate line PL4 is returned temporarily to the low level potential GND. The dummy “0” writing is then performed. At this time, as shown in FIG. 10, the sense amplifier S/A reduces the potential of the bit line BL to the low level potential GND. The plate line drive circuit PLD raises the plate lines PL1 to PL4 to the high level potential Vcc. Thus, the data “0” is thus written in the ferroelectric capacitors FC1 to FC4.

According to the data reading operation, the data is read from the unit cell UC1 close to the bit line BL to the unit cell UC4 farthest from the bit line BL. At this time, the cell transistor in a unit cell to be read and cell transistors between the unit cell to be read and the bit line BL are turned on.

The reference data used for detecting data is changed depending on the number of unit cells between the unit cell to be read and the bit line BL in the first embodiment. Thus, the sense amplifier S/A can detect the data accurately. If the capacitance of one ferroelectric capacitor is so much smaller than the capacitance of the bit line BL that it can be ignored, the dummy “0” writing operation and the change of the reference data are not required.

While the capacitances of the ferroelectric capacitors FC1 to FC4 can be the same in the first embodiment, the capacitances of the ferroelectric capacitors FC1 to FC4 can be increased gradually in the order from a unit cell close to the bit line BL to a unit cell farthest from the bit line BL. Influences exerted by the capacitances of the ferroelectric capacitors FC1 to FC3 on the apparent capacitance of the bit line BL can be thereby reduced.

The capacitances of the ferroelectric capacitors FC1 to FC4 are preferably determined by a ratio of the apparent capacitance of the bit line BL (Cbl+Cfc_{—}0) to the capacitance Cbl of the bit line BL ((Cbl+Cfc_{—}0)/Cbl). The reference data is thus fixed. Cbl indicates the capacitance of the bit line BL and Cfc_{—}0 indicates the total capacitance of a ferroelectric capacitor of a unit cell to be written and the ferroelectric capacitors of the unit cells intervening between the unit cell to be written and the bit line.

Cfci_{—}0 indicates the capacitance of a ferroelectric capacitor the data “0” is written. “i” indicates integer numbers of 1 to 4. For example, if the capacitance of the ferroelectric capacitor FC1 that the data “0” is written is indicated by Cfc1_{—}0, the capacitance of the ferroelectric capacitor FC2 that the data “1” is written is indicated by ((Cbl+Cfc1_{—}0)/Cbl)*Cfc1. Cfc1 indicates the capacitance of the ferroelectric capacitor FC1 that the data “1” is written. The capacitance of the ferroelectric capacitor that the data “1” is written data is considered to relay on an effective area of the ferroelectric capacitor.

The effective area of the ferroelectric capacitor FC2 is calculated by multiplying the effective area of the ferroelectric capacitor FC1 by ((Cbl+Cfc1_{—}0)/Cbl). Similarly, the effective area of the ferroelectric capacitor FC3 is calculated by multiplying the effective area of the ferroelectric capacitor FC1 by ((Cbl+Cfc1+Cfc2_{—}0)/Cbl). The effective area of the ferroelectric capacitor FC4 is calculated by multiplying the effective area of the ferroelectric capacitor FC1 by ((Cbl+Cfc1+Cfc2+Cfc3_{—}0)/Cbl). The reference data is thus fixed.

According to the first embodiment, the writing and reading operations described above eliminate the need for proving a bit line contact for every unit cell. Because the bit line contact BLC is provided for every cell string CS including a plurality of unit cells, the entire area occupied by a ferroelectric memory is reduced. The first embodiment allows a highly integrated ferroelectric memory to be manufactured inexpensively.

### Second Embodiment

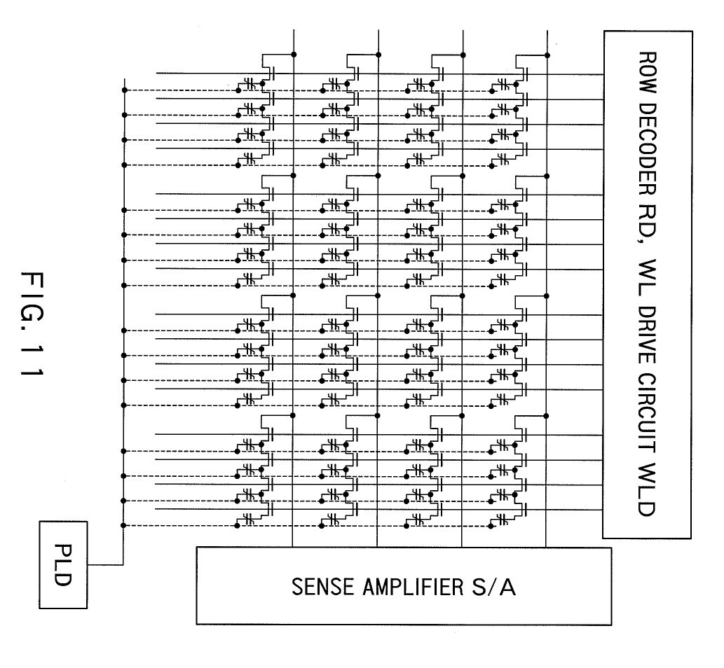

FIG. 11 shows a configuration of a ferroelectric memory according to a second embodiment of the present invention. In the second embodiment, the plate line PL is a common plate. The plate line drive circuit PLD applies the same potential to all plate lines PL. Other configurations of the second embodiment can be identical to those of the first embodiment.

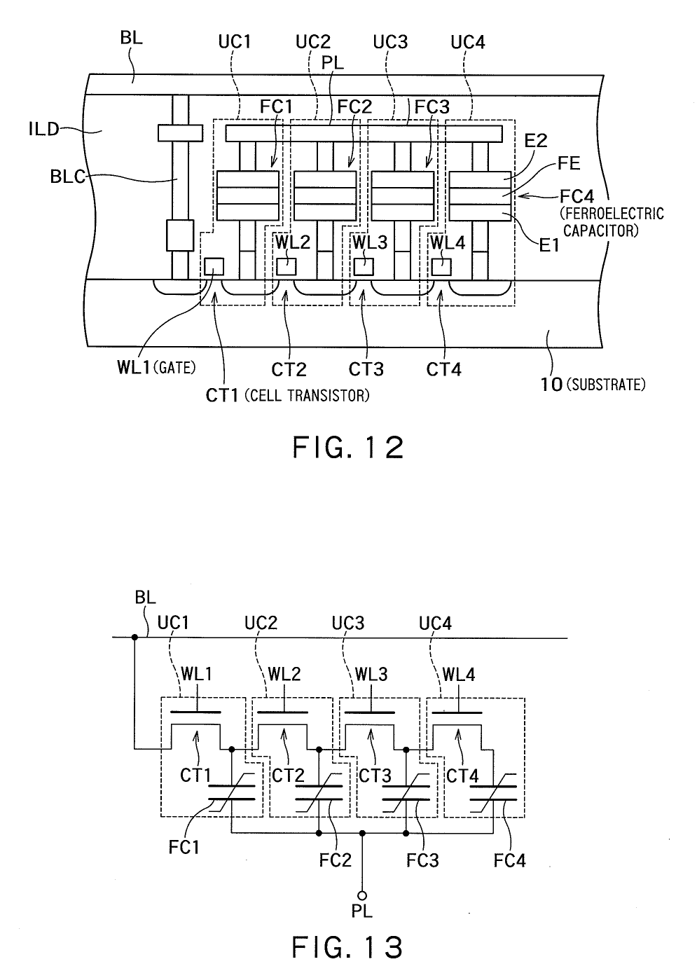

FIG. 12 is a cross-sectional view showing a configuration of the cell string CS according to the second embodiment. FIG. 13 is an equivalent circuit diagram of the cell string CS shown in FIG. 12. According to the second embodiment, the plate line drive circuit PLD does not drive selectively the potential of part of the plate lines PL. Instead, the plate line drive circuit PLD drives the potentials of all plate lines PL at a time. For the writing operation, the operations of PL1 to PL4 shown in FIG. 6 are performed for all plate lines PL. For the reading operation, the operation of PL 1 shown in FIG. 10 is performed for all plate lines PL. Other writing and reading operations in the second embodiment are identical to those in the first embodiment.

In this case, disturbances in unit cells that data have already written or in unit cells that data have not been read may become a concern. However, because the second terminal E2 in the unit cell that the data has already been written is disconnected from the bit line BL, it is in the floating state. Because the second terminal E2 in the unit cell that the data has not been read is disconnected from the bit line BL, it is in the floating state. Therefore, the potential difference to be applied to a ferroelectric capacitor that data has already been written is smaller than a potential difference to be applied to a ferroelectric capacitor to be written.

Similarly, a potential difference to be applied to a ferroelectric capacitor that data has not been read is smaller than a potential difference to be applied to a ferroelectric capacitor to be read. That is, the voltage difference sufficiently smaller than the high level potential Vcc applied to the plate line PL is applied to the ferroelectric capacitors that the data have already been written and have not been read. Because the data are hardly broken in such cases, problems do not occur if the plate line PL is common. For example, if a gradation of hysteresis loop of a ferroelectric capacitor is sufficient enough and a voltage applied to the capacitor is smaller than a coercive voltage, problems will not occur if the plate line PL is common.

In the case that the plate line PL is made of a first metal layer (M1) as shown in FIG. 12, if the plate line PL is common, it is formed without restrictions of a line/space (L/S). Therefore, the interval between adjacent unit cells is not restricted by the line/space (L/S) of the plate line PL. Accordingly, the interval between adjacent unit cells can be reduced, and thus the area occupied by a ferroelectric memory can be further reduced.

1. A ferroelectric memory device comprising:
a plurality of word lines;
a plurality of bit lines;
a plurality of plate lines;
a plurality of ferroelectric capacitors each of which includes a ferroelectric film between a first electrode and a second electrode;
a plurality of cell transistors corresponding to the ferroelectric capacitors; and
a bit line contact connecting the cell transistors to the bit line, wherein
the first electrode is connected to one of source and drain of the cell transistor at a first node, so that the ferroelectric capacitor and the cell transistor form a unit cell,
the other of source and drain of the cell transistor for the unit cell is connected to the first node of other unit cell to serially connect the cell transistors for a plurality of unit cells, so that the unit cells form a cell string,
the word lines are connected to gates of the cell transistors or function as gates,
the plate lines are connected to the second electrodes of the ferroelectric capacitors, and
the bit line is connected only to a cell transistor at an end of the cell string via the bit line contact.

2. The ferroelectric memory device according to claim 1, wherein in a data writing operation, the cell transistor of a first unit cell to be written and the cell transistors of the unit cells intervening between the first unit cell and the bit line are turned on.

3. The ferroelectric memory device according to claim 1, wherein in a data reading operation, the cell transistor of a second unit cell to be read and the cell transistors of the unit cells intervening between the second unit cell and the bit line are turned on.

4. The ferroelectric memory device according to claim 2, wherein in a data reading operation, the cell transistor of a second unit cell to be read and the cell transistors of the unit cells intervening between the second unit cell and the bit line are turned on.

5. The ferroelectric memory device according to claim 3, wherein in the data reading operation, reference data used for detecting data is changed depending on the number of the unit cells intervening between the second unit cell and the bit line.

6. The ferroelectric memory device according to claim 4, wherein in the data reading operation, reference data used for detecting data is changed depending on the number of the unit cells intervening between the second unit cell and the bit line.

7. The ferroelectric memory device according to claim 1, wherein the capacitances of the unit cells in a cell string are gradually increased in order from a unit cell close to the bit line to a unit cell far from the bit line.

8. The ferroelectric memory device according to claim 7, wherein the capacitances of the unit cells in a cell string are determined based on (Cbl+Cfc_{—}0)/Cbl) wherein
Cbl indicates the capacitance of the bit line and Cfc_{—}0 indicates the total capacitance of a ferroelectric capacitor of a first unit cell to be written and the ferroelectric capacitors of the unit cells intervening between the first unit cell and the bit line.

9. A ferroelectric memory device comprising:
a plurality of word lines;
a plurality of bit lines;
a plurality of plate lines connected to each other as a common plate;
a plurality of ferroelectric capacitors each of which includes a ferroelectric film between a first electrode and a second electrode;
a plurality of cell transistors corresponding to the ferroelectric capacitors; and
a bit line contact connecting the cell transistors to the bit line, wherein
the first electrode is connected to one of source and drain of the cell transistor at a first node, so that the ferroelectric capacitor and the cell transistor form a unit cell,
the other of source and drain of the cell transistor for the unit cell is connected to the first node of other unit cell to serially connect the cell transistors for a plurality of unit cells, so that the unit cells form a cell string,
the word lines are connected to gates of the cell transistors or function as gates,
the common plate is connected to the second electrodes of the ferroelectric capacitors, and
the bit line is connected only to a cell transistor at an end of the cell string via the bit line contact.

10. The ferroelectric memory device according to claim 9, wherein in a data writing operation, the cell transistor of a first unit cell to be written and the cell transistors of the unit cells intervening between the first unit cell and the bit line are turned on.

11. The ferroelectric memory device according to claim 9, wherein in a data reading operation, the cell transistor of a second unit cell to be read and the cell transistors of the unit cells intervening between the second unit cell and the bit line are turned on.

12. The ferroelectric memory device according to claim 10, wherein in a data reading operation, the cell transistor of a second unit cell to be read and the cell transistors of the unit cells intervening between the second unit cell and the bit line are turned on.

13. The ferroelectric memory device according to claim 11, wherein in the data reading operation, reference data used for detecting data is changed depending on the number of the unit cells intervening between the second unit cell and the bit line.

14. The ferroelectric memory device according to claim 12, wherein in the data reading operation, reference data used for detecting data is changed depending on the number of the unit cells intervening between the second unit cell and the bit line.

15. The ferroelectric memory device according to claim 9, wherein the capacitances of the unit cells in a cell string are gradually increased in order from a unit cell close to the bit line to a unit cell far from the bit line.

16. The ferroelectric memory device according to claim 15, wherein the capacitances of the unit cells in a cell string are determined based on (Cbl+Cfc_{—}0)/Cbl) wherein
Cbl indicates the capacitance of the bit line and Cfc_{—}0 indicates the total capacitance of a ferroelectric capacitor of a first unit cell to be written and the ferroelectric capacitors of the unit cells intervening between the first unit cell and the bit line.
